(19) United States
(12) Patent Application Publication
(10) Pub. No.: US 2012/0061715 A1
(43) Pub. Date: Mar. 15, 2012

(54) SEMICONDUCTOR LIGHT-EMITTING DEVICE MANUFACTURING METHOD AND SEMICONDUCTOR LIGHT-EMITTING DEVICE

(75) Inventors: Ji-Hao LIANG, Tokyo (JP); Tatsuma Saito, Tokyo (JP)

(73) Assignee: STANLEY ELECTRIC CO., LTD., Tokyo (JP)

(21) Appl. No.: 13/231,135

(22) Filed: Sep. 13, 2011

(30) Foreign Application Priority Data
Sep. 13, 2010 (JP) 2010-204353

(51) Int. Cl. H01L 33/62

(52) U.S. Cl. 257/99; 438/22; 257/E33.066

(57) ABSTRACT

There is provided a semiconductor light-emitting device manufacturing method which includes the steps of forming a semiconductor growth film on a growth substrate; forming a metal film on the semiconductor growth film; forming a multilayer insulating film on the metal film, the multilayer insulating film having at least a first insulating layer and a second insulating layer adjacent to each other; and forming a support member on the multilayer insulating film. Pinholes present in the first insulating layer are discontinuous with pinholes present in the second insulating layer at an interface between the first and the second insulating layers.

### BACKGROUND OF THE INVENTION

1. Technical Field

The present invention relates to a semiconductor light-emitting device manufacturing method and a semiconductor light-emitting device manufactured by carrying out the method; and particularly to a semiconductor light-emitting device manufacturing method for growing a semiconductor growth film on a growth substrate, supporting the semiconductor growth film by a support substrate, and subsequently removing the growth substrate; and a semiconductor light-emitting device manufactured by carrying out the method.

2. Description of the Related Art

A light-emitting diode (LED) and other semiconductor light-emitting elements have been used as a light source in a display apparatus, such as a backlight in a liquid crystal display as a typical example. In recent years, a semiconductor light-emitting element has also been used in the other fields of illumination apparatus such as a general illuminator, a vehicle light, and so on.

However, since higher light emission output than a display apparatus is required, an illumination apparatus may require a large amount of drive current, about 50 times the amount of drive current required in a display apparatus in some cases. For example, when a semiconductor light-emitting element is used as a light source of a backlight in a mobile phone liquid crystal display, drive current having a magnitude of about 20 milliampere (mA) is conducted through the semiconductor light-emitting element, whereas it is necessary to conduct drive current having a magnitude of about 1 ampere (A) through the semiconductor light-emitting element when a semiconductor element is used as a light source in an illumination apparatus. Since the amount of heat generated in such a semiconductor light-emitting element increases with the drive current, there is an increasing demand for quick dissipation of the heat generated in the semiconductor light-emitting element. To dissipate the heat, there is, for example, a method for supporting a semiconductor film grown on a growth substrate with a support substrate having heat conductivity higher than that of the growth substrate and subsequently removing the growth substrate having low heat conductivity. For example, Japanese Unexamined Patent Application Publication No. 2008-545267 (hereinafter also referred to as Patent Document 1) discloses a method for growing a semiconductor film on a sapphire substrate which is a growth substrate, and supporting the semiconductor film by a heat conductive insulating substrate having heat conductivity higher than that of the sapphire substrate.

Further, to achieve high light emission output, there is a known method for forming a plurality of semiconductor light-emitting elements (that is, arrayed semiconductor light-emitting elements) on a single growth substrate and serially connecting the plurality of semiconductor light-emitting elements to form a semiconductor light-emitting device formed of the plurality of semiconductor light-emitting elements. For example, Japanese Unexamined Patent Application Publication No. 2008-505478 (hereinafter also referred to as Patent Document 2) discloses formation of a semiconductor light-emitting device by serially connecting a plurality of semiconductor light-emitting elements formed on a sapphire substrate.

### SUMMARY OF THE INVENTION

Examples of a support substrate that has heat conductivity higher than that of a growth substrate (i.e., a substrate used for crystal growth) and excels in cost and productivity include a semiconductor substrate made of Si, Ge, GaAs or GaP or a conductive substrate made of Fe, an Fe alloy, Cu, a Cu alloy, Al, or an Al alloy. To support a plurality of light-emitting elements by any of the semiconductor substrates or the conductive substrate and serially connect the plurality of light-emitting elements, it is necessary to provide an insulating film between the semiconductor or conductive substrate and the semiconductor growth film. Since such an electrically insulating material has low heat conductivity, it is necessary to minimize the thickness of the insulating film.

However, an insulating film has a plurality of micro-sized through holes called pinholes. Therefore, when a bonding metal film is formed on the support substrate or an electrode metal film is formed on the semiconductor growth film, metal atoms in the metal film on the support substrate or metal atoms in the metal film on the semiconductor growth film move into and diffuse (or migrate) in the insulating film and form electrical short paths, resulting in a decrease in withstand voltage and reliability of the insulating film. That is, the electrical insulation property thereof decreases when the insulating film is thin. In this case, light emission output may disadvantageously decrease due to current leakage, and the element may not emit light at all in the worst case.

Even when the thickness of the insulating film is increased, the pinholes in the insulating film cannot be completely eliminated, and the insulation property of the insulating film decreases with time. Further, when the insulating film is thickened, the thermal resistance of the insulating film increases, which does not allow improvement in heat conductivity of the semiconductor light-emitting device.

The invention has been made in view of the circumstances described above, and an object of the invention is to provide a semiconductor light-emitting device manufacturing method for forming an insulating film having an excellent insulation property and high heat conductivity between a semiconductor growth film and a support member to increase the withstand voltage and improve the heat dissipation property of the semiconductor light-emitting device. Another object of the invention is to provide a semiconductor light-emitting device manufactured by carrying out the above method.

To achieve the object described above, a semiconductor light-emitting device manufacturing method according to the invention includes the steps of forming a semiconductor growth film on a growth substrate; forming a metal film on the semiconductor growth film; forming a multilayer insulating film on the metal film, the multilayer insulating film having at least a first insulating layer and a second insulating layer adjacent to each other; and forming a support member on the multilayer insulating film. Pinholes present in the first insulating layer are discontinuous with pinholes present in the second insulating layer at an interface between the first insulating layer and the second insulating layer.

To achieve the object described above, another semiconductor light-emitting device manufacturing method according to the invention includes steps of forming a semiconductor growth film on a growth substrate; forming a metal film on the semiconductor growth film; forming a multilayer insulating film formed of a first insulating layer and a second insulating layer by stacking the same insulating material on the metal film by a sputtering process; and forming a support member on the multilayer insulating film. In the step of forming the multilayer insulating film, a substrate temperature when forming the first insulating layer differs from a substrate temperature when forming the second insulating layer by at least 50° C.

To achieve the object described above, a semiconductor light-emitting device according to the invention includes a multilayer insulating film formed on a support member and having at least a first insulating layer and a second insulating layer adjacent to each other; a metal film formed on the multilayer insulating film; and a semiconductor growth film formed on the metal film. Pinholes present in the first insulating layer are discontinuous with pinholes present in the second insulating layer at an interface between the first insulating layer and the second insulating layer.

By carrying out any of the semiconductor light-emitting device manufacturing methods according to the invention, an insulating film is formed between a semiconductor growth film and a support member and has a multilayer structure that has an interface that causes pinholes present in a first insulating layer to be discontinuous with pinholes present in a second insulating layer adjacent to the first insulating layer. Since the degree of insulation of the insulating film is therefore increased, the insulating film can be thin while obtaining high heat conductivity. Further, a withstand voltage and a heat dissipation property of the semiconductor light-emitting device can be improved.

### BRIEF DESCRIPTION OF THE DRAWINGS

FIGS. 1A to 1E are cross-sectional views showing manufacturing steps in a semiconductor light-emitting device manufacturing method according to a first embodiment of the invention;

FIG. 2 is a cross-sectional view showing a semiconductor growth film having grown on a growth substrate;

FIGS. 3A to 3D are cross-sectional views showing manufacturing steps in the semiconductor light-emitting device manufacturing method according to the first embodiment of the invention;

FIG. 4A is a plan view of the semiconductor light-emitting device according to the first embodiment of the invention, and FIG. 4B is a cross-sectional view taken along the dashed line 4b-4b shown in FIG. 4A;

FIG. 5 is a cross-sectional view showing the structure of the semiconductor growth film that forms a semiconductor light-emitting element according to the first embodiment of the invention;

FIG. 6 is an enlarged, schematic cross-sectional view for illustrating the internal structure of an insulating film that forms the semiconductor light-emitting element according to the first embodiment of the invention;

FIG. 7 is a graph showing dielectric breakdown voltages of the semiconductor light-emitting device according to the first embodiment of the invention and dielectric breakdown voltages of semiconductor light-emitting devices according to Comparative Examples 1 to 3;

FIGS. 8A to 8D are graphs showing a substrate temperature when forming an insulating film versus an electrostatic withstand voltage; and

FIG. 9 is an enlarged, diagrammatic cross-sectional view for describing the internal structure of an insulating film that forms a semiconductor light-emitting element according to a second embodiment of the invention.

### DETAILED DESCRIPTION OF THE INVENTION

Embodiments of the invention will be described below in detail with reference to the accompanying drawings.

### First Embodiment

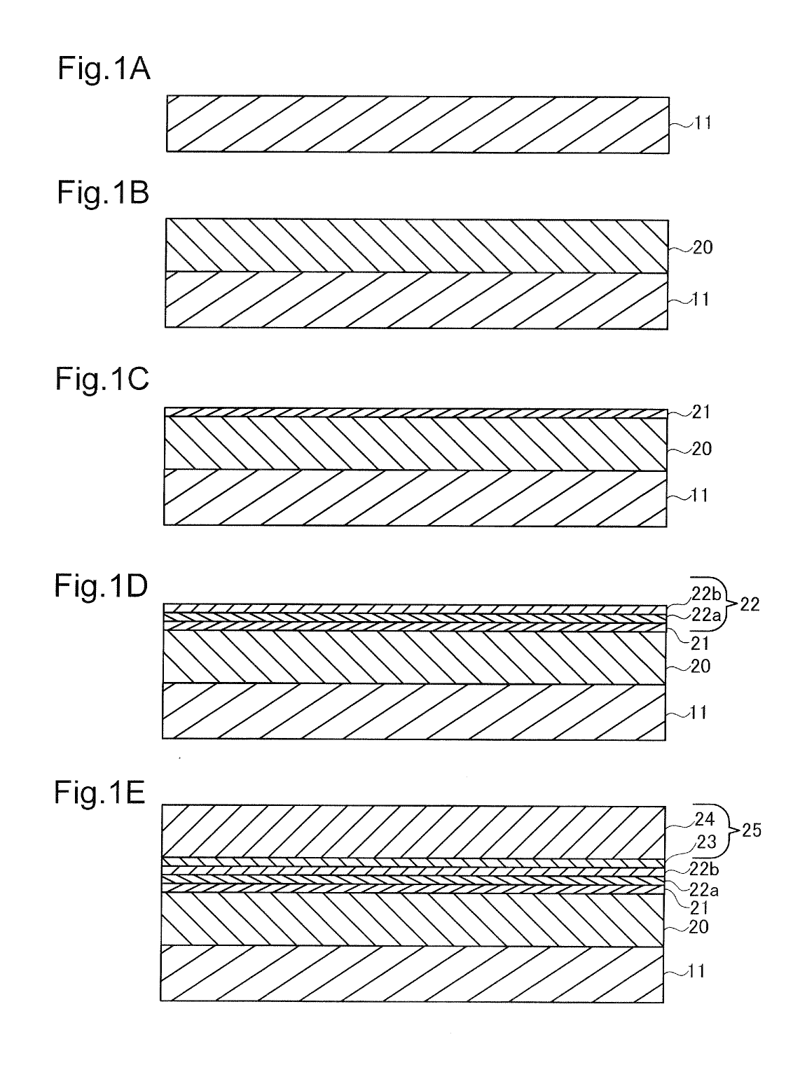

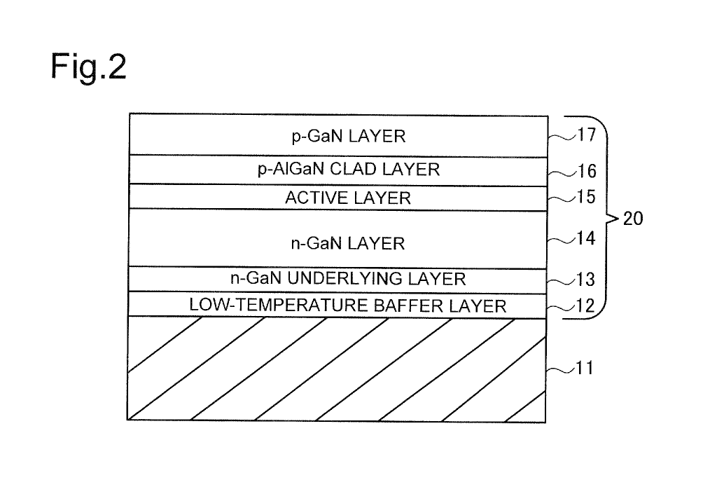

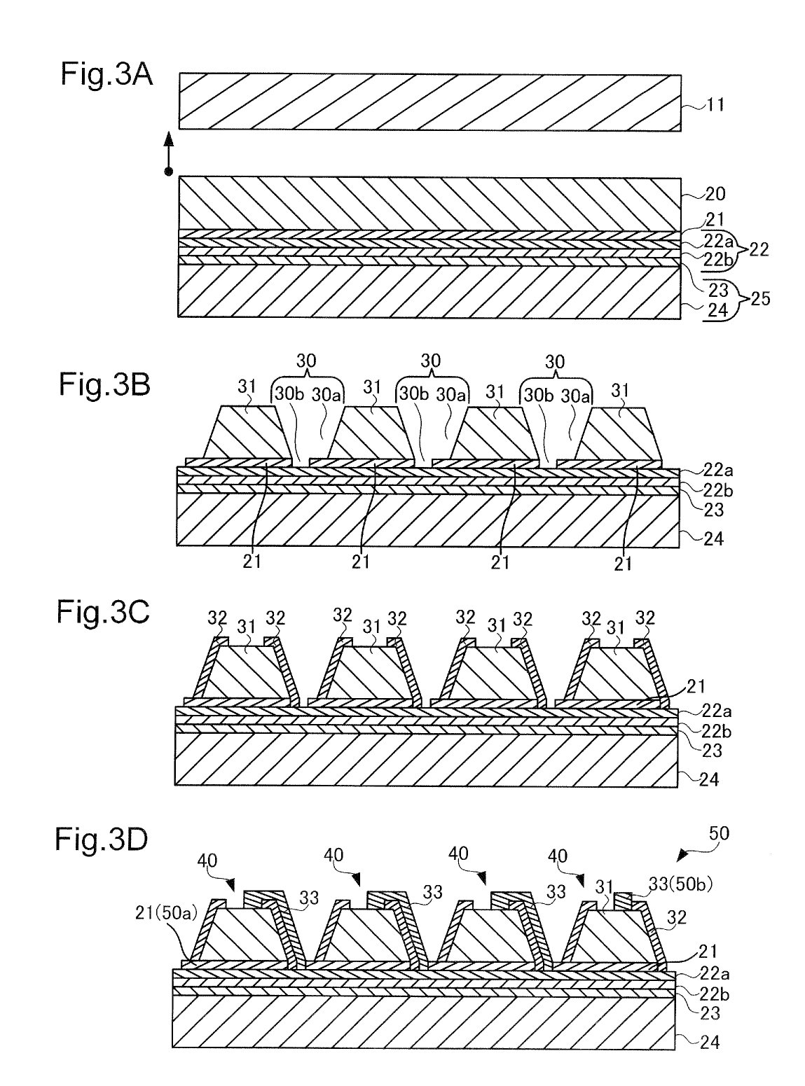

A semiconductor light-emitting device manufacturing method according to a first embodiment of the invention will first be described in detail with reference to FIGS. 1A to 1E, 2, and 3A to 3D. FIGS. 1A to 1E and 3A to 3D are cross-sectional views showing manufacturing steps in the semiconductor light-emitting device manufacturing method according to the first embodiment of the invention. FIG. 2 is a cross-sectional view showing a semiconductor growth film having grown on a growth substrate in a crystal growth process.

### [Growth Substrate Provision Step]

In the first embodiment of the invention, a C-plane sapphire substrate 11 (hereinafter simply referred to as a sapphire substrate 11) is provided as a substrate (i.e., growth substrate) on which a semiconductor growth film made of AlₓIn_{y}Ga_{z}N (0≦x≦1, 0≦y≦1, 0≦z≦1, x+y+z=1) is formed by a metal organic chemical vapor deposition (MOCVD) method (FIG. 1A). The growth substrate is not limited to a C-plane sapphire substrate but may, for example, be an R-plane sapphire substrate, a GaN substrate, an MgAl₂O₄ substrate, or an SiC substrate.

### [Semiconductor Growth Film Formation Step]

The sapphire substrate 11 is then heated in a hydrogen atmosphere at 1000 degrees Celsius (1000° C.) for 10 minutes for thermal cleaning. A semiconductor growth film 20 is then formed on the sapphire substrate 11 by an MOCVD method (FIG. 1B, FIG. 2). The semiconductor growth film 20 is formed of a low-temperature buffer layer 12, a GaN underlying layer 13, an n-GaN layer 14, an active layer 15, a p-AlGaN cladding layer 16, and a p-GaN layer 17. The semiconductor layers that form the semiconductor growth film 20 are sequentially stacked or layered on the sapphire substrate 11 along the C-axis direction of a wurtzite crystal structure by the MOCVD process.

More specifically, the low-temperature buffer layer 12 made of GaN is first formed on the sapphire substrate 11 by setting the temperature of the substrate (i.e., growth temperature) at 500° C. and supplying trimethyl gallium (TMG) (at a flow rate of 10.4 μmol/min) and NH₃ (at a flow rate of 3.3 LM) for about 3 minutes. The low-temperature buffer layer 12 is then crystallized by increasing the substrate temperature to 1000° C. and holding that temperature for about 30 seconds. The GaN underlying layer 13 is subsequently formed to a thickness of 1 μm by maintaining the substrate temperature at 1000° C. and supplying TMG (at a flow rate of 45 μmol/min) and NH₃ (at a flow rate of 4.4 LM) for about 20 minutes.

The n-GaN layer 14 is then formed to a thickness of 7 μm by maintaining the substrate temperature at 1000° C. and supplying TMG (at a flow rate of 45 μmol/min) and NH₃ (at a flow rate of 4.4 LM) as well as SiH₄ as a dopant gas (at a flow rate of 2.7×10⁻⁹ μmol/min) for about 120 minutes.

The active layer 15 is then formed on the n-GaN layer 14. In the first embodiment of the invention, the active layer 15 has a multi-quantum-well structure made of InGaN/GaN. That is, a unit of InGaN/GaN is stacked five times in a growth process. Specifically, an InGaN well layer is formed to a thickness of 2.2 nm by setting the substrate temperature at 700° C. and supplying TMG (at a flow rate of 3.6 μmol/min), trimethyl indium (TMI) (at a flow rate of 10 μmol/min), and NH₃ (at a flow rate of 4.4 LM) for about 33 seconds. A GaN barrier layer is subsequently formed to a thickness of 15 nm by supplying TMG (at a flow rate of 3.6 μmol/min) and NH₃ (at a flow rate of 4.4 LM) for about 320 seconds. The growth process described above is repeated five times to form the active layer 15.

The p-AlGaN cladding layer 16 is then formed to a thickness of about 40 nm by increasing the substrate temperature to 870° C. and supplying TMG (at a flow rate of 8.1 μmol/min), trimethyl aluminum (TMA) (at a flow rate of 7.5 μmol/min), and NH₃ (at a flow rate of 4.4 LM) as well as bis-cyclopentadienyl magnesium (Cp₂Mg) as a dopant (at a flow rate of 2.9×10⁻⁷ μmol/min) for about 5 minutes. The p-GaN layer 17 is subsequently formed to a thickness of about 150 nm by maintaining the substrate temperature and supplying TMG (at a flow rate of 18 μmol/min) and NH₃ (at a flow rate of 4.4 LM) as well as Cp₂Mg as a dopant (at a flow rate of 2.9×10⁻⁷ μmol/min) for about 7 minutes. The semiconductor growth film 20 formed of the semiconductor layers described above is thus formed on the sapphire substrate 11 (FIG. 2).

### [P-Side Electrode Formation Step]

A p-side electrode 21 is then formed on the semiconductor growth film 20 (FIG. 1C). More specifically, the p-side electrode 21, which is made of Pt/Ag/Ti, is formed by sequentially stacking Pt (1 nm), Ag (150 nm), and Ti (100 nm) to cover the surface of the p-GaN layer 17 of the semiconductor growth film 20 in an electron beam evaporation process. It is noted that the thickness of each of the metal layers is presented only by way of example and can be changed as appropriate. For example, the thickness of the Ti layer can be changed to any value within a range from 0.1 to 100 nm. Further, Pt in the p-side electrode 21 may be replaced with ITO (Indium Tin Oxide).

The p-side electrode 21, which has the stacked metal structure described above, provides excellent bonding property and excellent ohmic contact property with the semiconductor growth film 20. Further, the p-side electrode 21 efficiently reflects light emitted from the active layer 15.

### [Multilayer Insulating Film Formation Step]

An insulating film 22 having a two-layer structure (i.e., multilayer insulating film) is then formed on the p-side electrode 21 (FIG. 1D). Specifically, a first insulating layer 22a made of SiO₂ is first formed to a thickness of about 150 nm by a sputtering process. The sputtering is performed under the following conditions: a substrate temperature of about 50° C. (i.e., temperature without performing heating), a high-frequency electric power (RF power) of 500 W, a total pressure ranging from 0.07 to 0.1 Pascal (Pa), and an atmosphere gas partial pressure ratio of Ar:O₂=95%:5%. A second insulating layer 22b made of SiO₂ is then formed to a thickness of about 150 nm by a sputtering process. The sputtering is performed under the following conditions: a substrate temperature of about 300° C. (temperature with performing heating), a high-frequency electric power (RF power) of 500 W, a total pressure ranging from 0.07 to 0.1 Pascal (Pa), and an atmosphere gas partial pressure ratio of Ar:O₂=95%:5%. That is, the step for forming the first insulating layer 22a differs from the step for forming the second insulating layer 22b only in terms of substrate temperature (that is, film formation temperature), and the other conditions are the same.

In the present step, the first insulating layer 22a is formed at a low temperature (i.e., substrate temperature: 50° C.), and the second insulating layer 22b is then formed at a high temperature (i.e., substrate temperature: 300° C.). When the p-side electrode 21 includes an Ag layer, the Ag tends to aggregate in the high-temperature step (the sputtering at the substrate temperature of 300° C.), but the presence of the first insulating layer 22a formed at the low temperature (the sputtering at the substrate temperature of 50° C.) can prevent the Ag from aggregating.

The thickness of each of the first insulating layer 22a and the second insulating layer 22b may range from 50 to 600 nm. Further, the substrate temperature in the formation of the second insulating layer 22b may range from 150 to 300° C.

Ti that forms the p-side electrode 21 may be formed by sputtering before the first insulating layer 22a is formed.

### [Support Member Formation Step]

The resultant wafer after the steps described above are carried out is then bonded to a support substrate 24, which has been prepared in advance, with a bonding portion 23 therebetween (FIG. 1E). Specifically, a step is performed wherein Ti, Pt, Au, and AuSn are sequentially stacked on the insulating film 22 to form the bonding portion 23 made of Ti/Pt/Au/AuSn. The support substrate 24, which is made of Si, is so placed that it faces the bonding portion 23 and comes into intimate contact therewith. The bonding portion 23 and the support substrate 24 that have come into intimate contact with each other then undergo thermocompression bonding in a nitrogen atmosphere, whereby the support substrate 24 is bonded to the bonding portion 23 in a eutectic bonding process. The thermocompression bonding is performed under the following conditions: a pressure of about 300 N/cm², a temperature of about 280° C., and a compression period of about 10 minutes. A support member 25 formed of the bonding portion 23 and the support substrate 24 is formed by carrying out the step described above. The thermocompression bonding conditions described above are presented only by way of example. For example, the pressure may be changed to a value within a range from about 300 to 500 N/cm², and the temperature may be changed to a value within a range from about 280 to 370° C. as appropriate.

The support substrate 24 is not limited to a semiconductor substrate made of Si but may be a semiconductor substrate made, for example, of Ge, GaAs, or GaP or a conductive substrate made, for example, of Fe, an Fe alloy, Cu, a Cu alloy, Al, or an Al alloy. In the case of forming a support substrate made of any of Fe, an Fe alloy, Cu, a Cu alloy, Al, or an Al alloy in a plating process, the following steps are carried out to form the support member 25: Ti and Au are first sequentially stacked on the insulating film 22 to form the bonding portion 23 made of Ti/Au. The resultant wafer on which the bonding portion 23 has been formed is then immersed in a plating bath and Cu or any of the other substances described above is stacked on the bonding portion 23 in an electroplating process, whereby the support substrate 24 made of Cu is formed, and the support member 25 formed of the bonding portion 23 and the support substrate 24 is formed.

### [Growth Substrate Removal Step]

The sapphire substrate 11 is then removed from the semiconductor growth film 20 by a laser lift off (LLO) method (FIG. 3A). More specifically, the backside of the sapphire substrate 11 (i.e., the surface on which no semiconductor growth film 20 has been formed) is irradiated with eximer laser light. The wavelength of the eximer laser light is about 266 nm. The light source of the eximer laser light is a KrF eximer laser light source.

Sapphire is transparent to eximer laser light, whereas GaN, with which the semiconductor growth film 20 is formed, absorbs eximer laser light. In the first embodiment of the invention, part of the low-temperature buffer layer 12 and the GaN underlying layer 13 in the vicinity of the interface between the semiconductor growth film 20 and the sapphire substrate 11 is therefore decomposed into metal Ga and N₂ gas, whereby the sapphire substrate 11 is separated from the semiconductor growth film 20 along the portion irradiated with the laser light.

In the first embodiment of the invention, in which a KrF eximer laser is used as the laser light source, an ArF eximer laser that emits light having a wavelength of 193 nm or an

Nd:YAG laser that emits light having a wavelength of 266 nm may alternatively be used. It is noted that the surface of the n-GaN layer 14 of the semiconductor growth film 20 that is exposed when the GaN is decomposed as described above becomes a C-plane (or N-plane).

Further, in the first embodiment of the invention, in which the sapphire substrate 11 is separated by the LLO process, the sapphire substrate 11 may alternatively be removed by grinding and polishing processes or by a reactive ion etching (RIE) process. Still alternatively, when the growth substrate is made of a material that dissolves in a specific solution, the specific solution may be used to remove the growth substrate.

### [Element Segmentation Step]

An element segmentation groove 30 for dividing the wafer into individual semiconductor light-emitting elements is then formed in the semiconductor growth film 20 and the p-side electrode 21 (FIG. 3B).

Specifically, a resist is first applied onto the surface of the semiconductor growth film 20. The resist is subsequently patterned in a grid pattern by a photolithography process. The wafer on which the resist described above has been formed is then placed in a reactive ion etching device. The patterned resist is used as a mask and Cl₂ plasma-based dry etching is performed on the semiconductor growth film 20, whereby an element segmentation groove 30a that has a grid pattern and reaches the p-side electrode 21 is formed in the semiconductor growth film 20. The element segmentation groove 30a segments the semiconductor growth film 20 into element portions (element regions) one side of each of which is, for example, about 1 mm in length. A plurality of element portions 31 is thus formed.

The width of the opening of the element segmentation groove 30a gradually decreases in the direction from the n-GaN layer 14 (i.e., the surface exposed in LLO process) of the semiconductor growth film 20 toward the p-side electrode 21. In other words, each of the element portions 31 has a trapezoidal cross-sectional shape, and the side portion of the element portions 31 are so inclined that the width of the cross-sectional shape increases in the direction from the n-GaN layer 14 toward the p-GaN layer 17. That is, forming the element segmentation groove 30a causes the side surface of each of the element portions 31 to be tapered and inclined to the p-side electrode 21.

A resist is then applied onto the semiconductor growth film 20 and the exposed p-side electrode 21. The resist is subsequently patterned in a grid pattern in a photolithography process. The wafer on which the resist described above has been formed is then placed in a reactive ion etching device. The patterned resist is used as a mask, and wet etching using hydrochloric acid, nitric acid, or a mixture of acetic acid, phosphoric acid, and nitric acid is performed on the p-side electrode 21, whereby an element segmentation groove 30b that has a grid pattern and reaches the first insulating layer 22a is formed in the p-side electrode 21. The element segmentation groove 30b segments the p-side electrode 21 into segmented p-side electrodes 21, each of which is individually formed on the corresponding element portion 31. Forming the element segmentation groove 30a and the element segmentation groove 30b completes the formation of the element segmentation groove 30 that penetrates through the semiconductor growth film 20 and the p-side electrode 21 and reaches the first insulating layer 22a.

In the first embodiment of the invention, the element segmentation groove 30a is formed using the dry etching process, but the method for forming the element segmentation groove 30a is not limited to dry etching. For example, the element segmentation groove 30a may alternatively be formed by a wet etching process using KOH, NaOH, or any other suitable alkali solution or in a method combining the wet etching and the dry etching described above. Further, in the first embodiment of the invention, in which the element segmentation groove 30b is formed by the wet etching process, the element segmentation groove 30b may alternatively be formed by a dry etching process or by a process combining dry etching and the wet etching described above.

### [Protective Film Formation Step]

Protective films 32 that cover the following portions are formed: part of the side surface of each of the segmented p-side electrodes 21 that has been exposed by the element segmentation groove 30b, the side surfaces (inclined surface of side portion) of the element portions 31, and part of the n-GaN layer 14 of each of the element portions 31 (the surface exposed in the LLO process) (FIG. 3C).

Specifically, a resist is first so applied that it covers the exposed first insulating layer 22a, p-side electrodes 21, and element portions 31, and the resist is then patterned in a photolithography process. An SiO₂ film is subsequently formed by a sputtering process, a chemical vapor deposition (CVD) process, an evaporation process, or any other known film formation process. The SiO₂ film is formed, for example, to a thickness of about 350 nm. The patterned resist and unnecessary SiO₂ are then removed. The formation of the protective films 32 is thus completed. The protective films 32 are so formed that they cover part of the side surface of each of the p-side electrodes 21 that has been exposed by the element segmentation groove 30b, the side surfaces of the element portions 31, and part of the n-GaN layer 14 of each of the element portions 31 (i.e., the surface exposed in the LLO process). That is, no protective film 32 is formed on part of each of the p-side electrodes 21 or part of the surface of each of the n-GaN layers 14, The reason for this is that an n-side electrode, which will be described later, is used to electrically connect the n-GaN layer 14 of each of the element portions 31 to the p-side electrode 21 of the adjacent element portion 31.

The protective films are formed by a lift-off method in the above description, but an SiO₂ film may alternatively be first formed and the formed SiO₂ film may then be etched into a desired shape.

### [N-Side Electrode Formation Step]

An n-side electrode 33 is then formed to electrically connect the n-GaN layer 14 of each of the element portions 31 to the p-side electrode 21 of the adjacent element portion 31 (FIG. 3D).

More specifically, a resist is first so applied that it covers the exposed first insulating layer 22a, the p-side electrodes 21, and the element portions 31, and the resist is then patterned in a photolithography process. In this example, the resist is so patterned that each n-side electrode 33 to be formed extends from the surface of the n-GaN layer 14 of the corresponding element portion 31 along the surface of the corresponding protective film 32 to the exposed side surface of the p-side electrode 21 of the adjacent element portion 31. Ti, Al, Ti, and Au are sequentially stacked in the openings of the patterned resist by an electron beam evaporation process. The resist is then removed, whereby the n-side electrodes 33 made of Ti/Al/Ti/Au are formed. After the n-side electrodes 33 are formed, a plurality of semiconductor light-emitting elements 40 supported by the support member 25 with the insulating film 22 therebetween are formed.

In the present step, a semiconductor light-emitting device 50 formed of four semiconductor light-emitting elements 40 is formed by serially connecting four element portions 31 with the corresponding n-side electrodes 33. As a result, the p-side electrode 21 corresponding to a p-side external connection terminal 50a in the semiconductor light-emitting device 50 is not connected to the n-side electrode 33 of the adjacent semiconductor light-emitting element 40. Further, the n-side electrode 33 corresponding to an n-side external connection terminal 50b in the semiconductor light-emitting device 50 is formed only on the corresponding n-GaN layer 14.

### [Device Division Step]

The support member 25 and the insulating film 22 are cut by irradiating the insulating film 22 with YAG laser light, whereby the wafer having undergone the steps described above is divided into semiconductor light-emitting devices 50 (into chips), each of which is formed of four semiconductor light-emitting elements 40. The device division process is not necessarily carried out by YAG laser light irradiation, and alternatively dicing or point scribing/breaking can be used.

After the steps described above, the formation of the semiconductor light-emitting device 50 according to the first embodiment of the invention is completed.

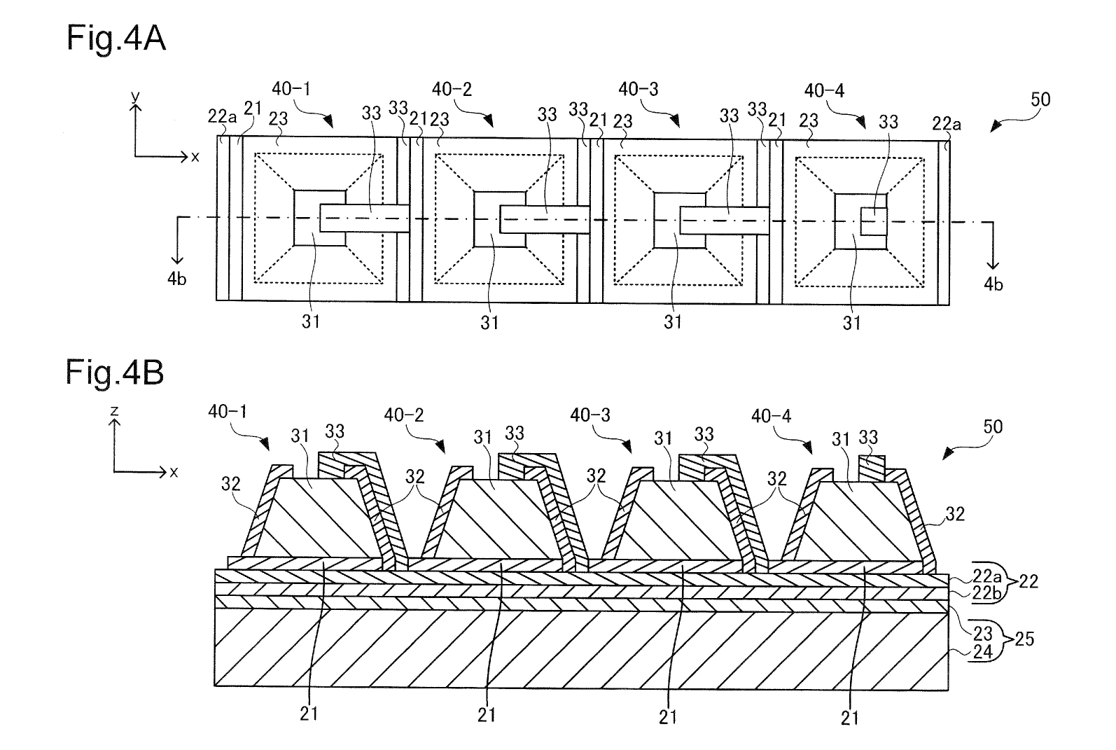

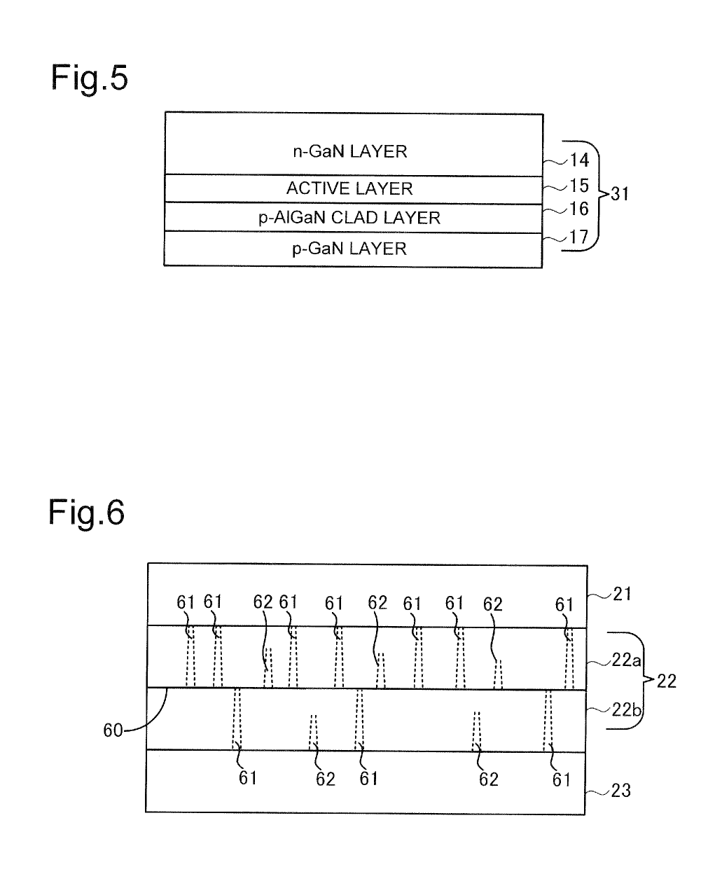

The structure of the semiconductor light-emitting device manufactured by carrying out the manufacturing method according to the first embodiment of the invention described above will be described with reference to FIGS. 4A and 4B, 5, and 6. FIG. 4A is a plan view of the semiconductor light-emitting device according to the first embodiment of the invention. FIG. 4B is a cross-sectional view taken along the line 4b-4b (indicated by the dashed line) shown in FIG. 4A. FIG. 5 is a cross-sectional view showing the structure of the semiconductor growth film in the semiconductor light-emitting element according to the first embodiment of the invention. FIG. 6 is an enlarged, diagrammatic cross-sectional view for describing the internal structure of the insulating film in the semiconductor light-emitting element according to the first embodiment of the invention.

The semiconductor light-emitting device 50 includes the insulating film 22, the support member 25, and four semiconductor light-emitting elements 40-1, 40-2, 40-3, and 40-4 (simply referred to as semiconductor light-emitting elements 40 in the following description when it is not necessary to specify any one of the semiconductor light-emitting elements), as shown in FIGS. 4A and 4B. Each of the semiconductor light-emitting elements 40 includes the p-side electrode 21, the element portion 31, the protective film 32, and the n-side electrode 33. The element portion 31 has a stacked structure in which the n-GaN layer 14, the active layer 15, the p-AlGaN cladding layer 16, and the p-GaN layer 17 are sequentially stacked in the direction from the n-side electrode 33 toward the p-side electrode 21, as shown in FIG. 5.

The support member 25 is formed of the bonding portion 23 and the support substrate 24. The support substrate 24 is a semiconductor substrate made of Si. The support substrate 24 has a rectangular shape in a plan view and has a dimension of about 4 millimeters (mm) in an x-axis direction (longer-side direction of the semiconductor light-emitting device 50) and a dimension of about 1 mm in a y-axis direction (shorter-side direction of the semiconductor light-emitting device 50). The support substrate 24 is not limited to a semiconductor substrate made of Si but may be a semiconductor substrate made, for example, of Ge, GaAs, or GaP or a conductive substrate made, for example, of Fe, an Fe alloy, Cu, a Cu alloy, Al, or an Al alloy. The bonding portion 23 is so formed that it covers the surface of the support substrate 24. The bonding portion 23 is made of Ti/Pt/Au/Sn. The semiconductor light-emitting elements 40 are supported by the common support substrate 24 with the bonding portion 23 allowing the support substrate 24 and the insulating film 22 to be in intimate contact with each other.

The semiconductor light-emitting elements 40 are juxtaposed along one direction (the x-axis direction) in FIG. 4A, and adjacent semiconductor light-emitting elements 40 are electrically connected to each other. Specifically, the n-side electrode 33 that is part of each semiconductor light-emitting element 40 extends to the p-side electrode 21 of the adjacent semiconductor light-emitting element 40, whereby adjacent semiconductor light-emitting elements 40 are connected to each other. More specifically, the n-side electrode 33 of the semiconductor light-emitting element 40-1 is connected to the p-side electrode 21 of the semiconductor light-emitting element 40-2; the n-side electrode 33 of the semiconductor light-emitting element 40-2 is connected to the p-side electrode 21 of the semiconductor light-emitting element 40-3; and the n-side electrode 33 of the semiconductor light-emitting element 40-3 is connected to the p-side electrode 21 of the semiconductor light-emitting element 40-4. Further, the p-side electrode 21 of the semiconductor light-emitting element 40-1 and the n-side electrode 33 of the semiconductor light-emitting element 40-4 function as external connection terminals. Each of the semiconductor light-emitting elements 40 has a square shape in a plan view and has a dimension of about 1 mm in the x-axis direction and a dimension of about 1 mm in the y-axis direction.

Each of the element portions 31 has a trapezoidal cross-sectional shape and the side portion of the element portion 31 is so inclined that the width thereof gradually decreases in the direction from the p-side electrode 21 toward the n-side electrode 33 formed on the surface of the element portion 31 (that is, in a +z direction), as shown in FIG. 4B. Since the side portion of the element portion 31 is inclined as described above, the protective film 32 can be easily formed on the inclined surface.

The p-side electrode 21 is formed on the surface of the p-GaN layer 17 (that is, the p-side surface). The n-side electrode 33 is formed on the surface of the n-GaN layer (that is, the n-side surface) and on the protective film 32. More specifically, the n-side electrode 33 is so formed that it covers the protective film 32 and part of the n-GaN layer 14 to electrically connect the n-GaN layer 14 to the p-side electrode 21 of the adjacent semiconductor light-emitting element 40. The p-side electrode 21 has a structure in which Pt, Ag, and Ti are sequentially stacked (Pt/Ag/Ti structure), and the n-side electrode 33 has a structure in which Ti, Al, Ti, and Au are sequentially stacked (Ti/Al/Ti/Au structure). Pt contained in the p-side electrode 21 may be replaced by ITO.

The protective film 32 is an oxide film made of SiO₂. The protective film 32 is so formed that it covers the side surface of the element portion 31. The protective film 32 is also formed on part of the surface of the n-GaN layer 14. The protective film 32 also covers part of the side surface of the p-side electrode 21 so that the p-side electrode 21 is not connected to the p-side electrode 21 of the adjacent semiconductor light-emitting element 40.

The insulating film 22 is formed of the first insulating layer 22a having a thickness about 150 nm and the second insulating layer 22b having a thickness of about 150 nm. The first insulating layer 22a and the second insulating layer 22b are made of SiO₂. The insulating film 22 prevents the four semiconductor light-emitting elements 40 from being electrically connected to each other via the bonding portion 23 made of a conductive material.

The first insulating layer 22a and the second insulating layer 22b have a plurality of pinholes 61 that penetrate therethrough and a plurality of pinholes 62 that do not penetrate therethrough (that is, those that start in the insulating layers), as shown in FIG. 6. Each of the pinholes 61 and 62 has a microscopic dimension. The density of the pinholes in the first insulating layer 22a is higher than that in the second insulating layer 22b.

The reason why the pinhole densities differ from each other will be described below. First of all, residual stress in the insulating film affects the formation of the pinholes 61 and 62. The residual stress used herein is a stress that acts in the direction in which the insulating film shrinks when the insulating film formed at a high substrate temperature (substrate temperature higher than about 25° C.) is exposed to a temperature lower than the temperature at the time of formation. When there is no difference in residual stress between the first insulating layer 22a and the second insulating layer 22b, the pinholes 61 in the first insulating layer 22a keep being formed in the second insulating layer 22b, whereby the pinholes 61 in the first insulating layer 22a are connected to the pinholes 61 in the second insulating layer 22b, resulting in pinholes that penetrate through the insulating film 22.

In the first embodiment of the invention, however, the substrate temperature when forming the first insulating layer 22a is 50° C., whereas the substrate temperature when forming the second insulating layer 22b is 300° C. The residual stress in the first insulating layer 22a is therefore smaller than the residual stress in the second insulating layer 22b. When there is a difference in the residual stress between the insulating layers, the pinholes 61 and 62 are produced in the second insulating layer 22b without being affected by the pinholes 61 and 62 present in the first insulating layer 22a. As a result, the pinholes 61 present in the first insulating layer 22a are not continuous with the pinholes 61 present in the second insulating layer 22b at an interface 60 between the first insulating layer 22a and the second insulating layer 22b. That is, the interface 60 prevents the pinholes from penetrating through the insulating film 22. When no pinhole penetrating through the insulating film 22 is present, migration of metal atoms that form the p-side electrode 21 and the bonding portion 23 sandwiching the insulating film 22 can be prevented and no short path is produced in the insulating film 22, whereby the withstand voltage and reliability of the insulating film 22 can be improved.

In the first embodiment of the invention described above, in which the semiconductor light-emitting elements 40 are serially disposed, the semiconductor light-emitting elements 40 may alternatively be disposed on the insulating film 22 in a matrix of two rows by two columns. Further, in the first embodiment of the invention described above, in which the semiconductor light-emitting device 50 is formed by serially connecting four semiconductor light-emitting elements 40, the semiconductor light-emitting device 50 may alternatively be formed of a single semiconductor light-emitting element 40. Moreover, in the first embodiment of the invention described above, in which the sapphire substrate 11, which is the growth substrate, is removed, the semiconductor light-emitting device may be formed by using a GaN substrate as the growth substrate and leaving the GaN substrate, which is the growth substrate.

In the first embodiment of the invention described above, in which the insulating film 22 has a two-layer structure, the insulating film 22 may alternatively have a structure in which three or more layers are stacked. In this case, the substrate temperature when forming each of the insulating layers also desirably differs from the substrate temperature when forming the other insulating layers. Further, in the first embodiment of the invention described above, in which the substrate temperature when forming the first insulating layer 22a differs from the substrate temperature when forming the second insulating layer 22b by about 250° C., the temperature difference is not limited thereto but may be any value that is at least 50° C.

In the first embodiment of the invention described above, in which the insulating film 22 is formed by a sputtering process, the insulating film 22 may alternatively be formed by a thermal CVD process, a plasma CVD process, an electron beam evaporation process, or a spin on glass (SOG) application process. When any of the other film formation methods is used, the substrate temperature when forming the first insulating layer 22a also desirably differs from the substrate temperature when forming the second insulating layer 22b by at least 50° C. Further, in the first embodiment of the invention described above, in which the insulating film 22 is made of SiO₂, the insulating film 22 may alternatively be made of SiN, Al₂O₃, or AlN.

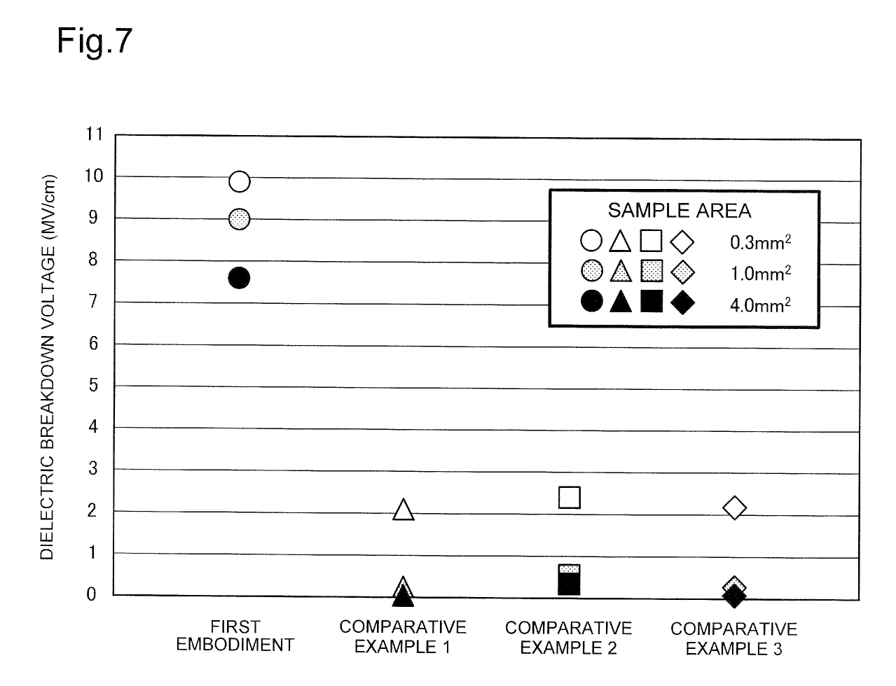

A dielectric breakdown voltage of the semiconductor light-emitting device 50 manufactured by carrying out the manufacturing method according to the first embodiment of the invention will next be compared with dielectric breakdown voltages of semiconductor light-emitting devices manufactured by carrying out manufacturing methods different from the manufacturing method according to the first embodiment of the invention (Comparative Examples 1, 2, and 3) with reference to FIG. 7. The manufacturing conditions in Comparative Examples 1 to 3 are described below. The difference in the manufacturing conditions between the first embodiment of the invention and Comparative Examples 1 to 3 is only the insulating film formation step, and therefore only this step will be described below.

### [Insulating Film Formation Step in Comparative Example 1]

After the p-side electrode is formed, an insulating film made of SiO₂ is formed to a thickness of about 300 nm by sputtering. The sputtering is performed under the following conditions: a substrate temperature of about 50° C. (i.e., temperature without performing heating), a high-frequency electric power (RF power) of 500 W, a total pressure ranging from 0.07 to 0.1 Pascal (Pa), and an atmosphere gas partial pressure ratio of Ar:O₂=95%:5%. That is, the insulating film in Comparative Example 1 has a monolayer structure, and the substrate temperature at the time of the film formation is about 50° C., which is equal to the substrate temperature when forming the first insulating layer 22a in the first embodiment of the invention.

### [Insulating Film Formation Step in Comparative Example 2]

After the p-side electrode is formed, an insulating film made of SiO₂ is formed to a thickness of about 300 nm by a sputtering process. The sputtering is performed under the following conditions: a substrate temperature of about 300° C. (i.e., temperature with performing heating), a high-frequency electric power (RF power) of 500 W, a total pressure ranging from 0.07 to 0.1 Pascal (Pa), and an atmosphere gas partial pressure ratio of Ar:O₂=95%:5%. That is, the insulating film in Comparative Example 2 has a monolayer structure, and the substrate temperature at the time of the film formation is about 300° C., which is equal to the substrate temperature when forming the second insulating layer 22b in the first embodiment of the invention.

[Insulating film Formation Step in Comparative Example 3]

After the p-side electrode is formed, a first insulating layer made of SiO₂ is formed to a thickness of about 150 nm by a sputtering process. The sputtering is performed under the following conditions: a substrate temperature of about 50° C. (i.e., temperature without performing heating), a high-frequency electric power (RF power) of 500 W, a total pressure ranging from 0.07 to 0.1 Pascal (Pa), and an atmosphere gas partial pressure ratio of Ar:O₂=95%:5%. The wafer on which the first insulating layer has been formed is then temporarily removed out of a film-formation device, and the removed wafer is placed again in the film-formation device. A second insulating layer made of SiO₂ is then formed to a thickness of about 150 nm by a sputtering process. The sputtering is performed under the following conditions: a substrate temperature of about 50° C. (i.e., temperature without performing heating), a high-frequency electric power (RF power) of 500 W, a total pressure ranging from 0.07 to 0.1 Pascal (Pa), and an atmosphere gas partial pressure ratio of Ar:O₂=95%:5%. That is, the insulating film in Comparative Example 3 has a two-layer structure, as in the case of the insulting film 22 in the first embodiment of the invention. Further, no difference in the substrate temperature is provided between the formation of the first and second insulating layers, and the substrate temperature when forming the first and second insulating layers is about 50° C., which is equal to the substrate temperature when forming the first insulating layer 22a in the first embodiment of the invention.

In the dielectric breakdown evaluation of the semiconductor light-emitting devices (hereinafter also referred to as samples) according to the first embodiment of the invention and Comparative Examples 1 to 3, three types of sample, that is, three types of sample area (that is, area of the insulating film: S=0.3, 1.0, and 4.0 mm²), were evaluated for each of the first embodiment of the invention and Comparative Examples 1 to 3.

FIG. 7 is a graph showing the dielectric breakdown voltages of the semiconductor light-emitting devices 50 according to the first embodiment of the invention and the semiconductor light-emitting devices according to Comparative Examples 1 to 3. FIG. 7 shows that the samples according to the first embodiment of the invention have dielectric breakdown voltages higher than those of the samples according to Comparative Examples 1 to 3 and hence are deemed to have improved withstand voltages. More specifically, the samples according to the first embodiment of the invention are found to have withstand voltages about ten times to several ten times higher than the withstand voltages according to Comparative Examples 1 to 3 when the sample area is large (S=1.0 mm² and 4.0 mm²).

Further, among the samples according to the first embodiment of the invention, the sample having the largest area (S=4.0 mm²) has a dielectric breakdown voltage slightly lower than those of the other samples. The reason for this is believed to be that the number of pinholes 61 present in the insulating film 22 increases with the sample area. The sample having the largest area (S=4.0 mm²) according to the first embodiment of the invention, however, also shows a dielectric breakdown voltage significantly higher than those of the samples according to Comparative Examples 1 to 3, although slightly lower than those of the other samples according to the first embodiment of the invention.

Further, in the samples that provide dielectric breakdown voltages lower than or equal to about 1 MV/cm, the pinholes are assumed to penetrate through the insulating film. In each of the samples according to Comparative Examples 1 to 3 that have the smallest area(S=0.3 mm²), the dielectric breakdown voltage is slightly improved as compared with those of the other samples. The reason for this is believed to be that the probability of the presence of pinholes that penetrate through the insulating film is low.

As described above, each of the samples according to the first embodiment of the invention achieves an extremely high dielectric breakdown voltage irrespective of the sample area. When the samples according to the first embodiment of the invention are compared with the samples according to Comparative Examples 1 to 3, the withstand voltage of the sample having a large sample area (S=4.0 mm²) according to the first embodiment of the invention is found to be particularly improved.

Next, consider six types of semiconductor light-emitting device 50 including insulating films 22 that are 50, 100, 500, 1000, 2000, and 5000 nm in thickness. Table 1 shows the thermal resistance of the insulating film 22 and an increase in temperature at the PN junction in one of the element portions 31 produced when an electric power of 20 W is supplied to the six types of semiconductor light-emitting device 50.

TABLE 1
Increase in temperature at PN junction due to
thermal resistance of insulating film

| | | | Increase in | |
|---|---|---|---|---|
| Thickness of | | Thermal resistance | temperature at PN | |
| insulating film | | of insulating film | junction | |
| 50 | nm | 0.01° C./W | 0.2° | C. |
| 100 | nm | 0.02° C./W | 0.4° | C. |
| 500 | nm | 0.09° C./W | 1.8° | C. |
| 1000 | nm | 0.17° C./W | 3.4° | C. |
| 2000 | nm | 0.34° C./W | 6.8° | C. |
| 5000 | nm | 0.85° C./W | 17.0° | C. |

As shown in Table 1, the thermal resistance of the insulating film 22 and the increase in temperature at the PN junction in the element portion 31 increase with the thickness of the insulating film 22. When the thickness of the insulating film 22 is 500 nm or smaller, the increase in the temperature is 1.8° C. or smaller. When the thickness of the insulating film 22 is 500 nm or smaller, the increase in the temperature is about one-half or smaller than the increase in the temperature produced when the thickness of the insulating film 22 is 1000 nm.

As shown in FIG. 7, the semiconductor light-emitting devices 50 having the insulating films 22 formed by carrying out the insulating film formation step according to the first embodiment of the invention show excellent withstand voltages, whereas the semiconductor light-emitting devices having the insulating films formed by carrying out the insulating film formation steps of related art in Comparative Examples 1 to 3 do not show any excellent withstand voltage. In consideration of the results shown in FIG. 7 and Table 1, the semiconductor light-emitting devices according to Comparative Examples 1 to 3 need to have thicker insulating films (1000 nm or thicker, for example) in order to improve the withstand voltages. Increasing the thickness of the insulating film, however, increases the thermal resistance as shown in Table 1, which reduces the heat dissipation ability of the semiconductor light-emitting devices. In contrast, each of the semiconductor light-emitting devices 50 according to the first embodiment of the invention shows an excellent withstand voltage and the insulating film 22 can be thin (500 nm or thinner, for example), whereby the thermal resistance of the insulating film 22 decreases, which improves the heat dissipation ability of the semiconductor light-emitting device 50. That is, the withstand voltage and the heat dissipation ability cannot be improved at the same time by carrying out the manufacturing methods of the related art due to a trade-off relationship between the withstand voltage and the heat dissipation ability. In contrast, the manufacturing method according to the first embodiment of the invention allows both the withstand voltage and the heat dissipation ability to be improved.

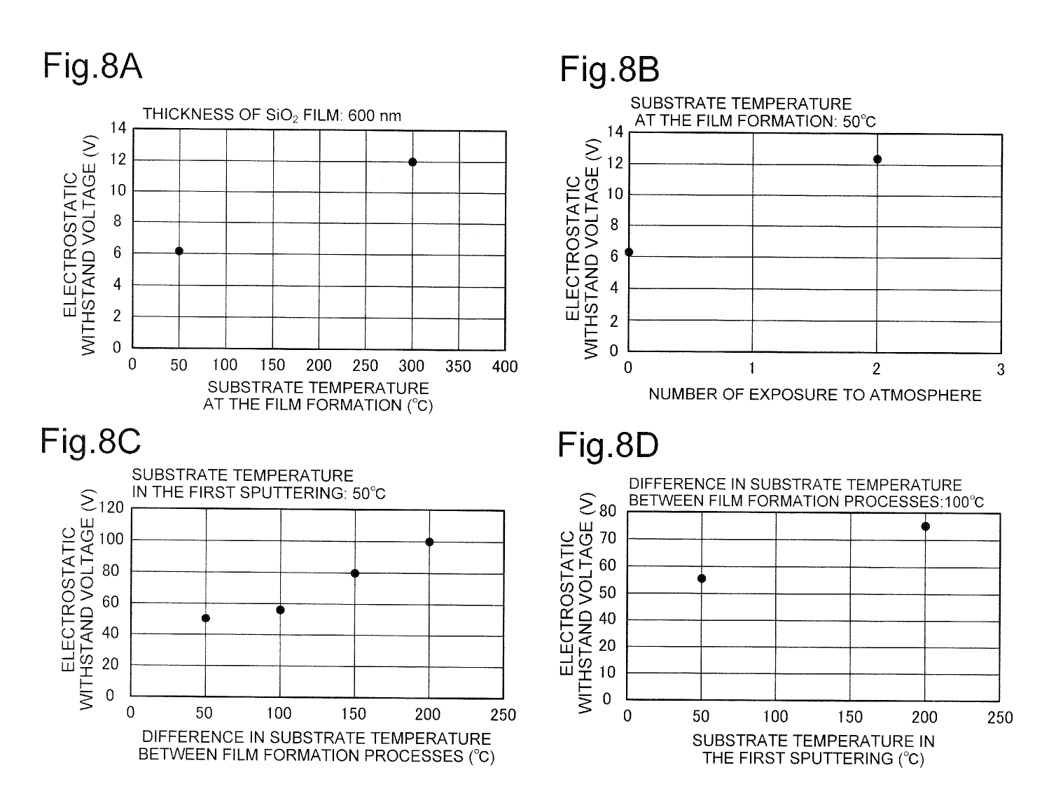

A description will next be made of a phenomenon in which an electrostatic withstand voltage of a semiconductor light-emitting device varies with the substrate temperature when forming the insulating film, with reference to Table 2 and FIGS. 8A to 8D. Table 2 shows results of an evaluation of the relationship between the substrate temperature and the electrostatic withstand voltage tested for semiconductor light-emitting devices having insulating films formed in various sputtering processes. Specifically, the electrostatic withstand voltage of the following samples was measured and evaluated: a semiconductor light-emitting device having an insulating film (film thickness: 600 nm) formed by a single sputtering process (substrate temperature: 50° C.) (sample A), a semiconductor light-emitting device having an insulating film (film thickness: 600 nm) formed by repeating a sputtering process (substrate temperature: 50° C., film thickness: 200 nm) three times (performing first to third sputtering) (sample B), a semiconductor light-emitting device having an insulating film (film thickness: 600 nm) formed by repeating a sputtering process (substrate temperature: 300° C., film thickness: 300 nm) twice (performing first and second sputtering) (sample C), a semiconductor light-emitting device having an insulating film (film thickness: 600 nm) formed by performing a first sputtering process (substrate temperature: 50° C., film thickness: 300 nm) and a second sputtering process (substrate temperature: 100° C., film thickness: 300 nm) (sample D), a semiconductor light-emitting device having an insulating film (film thickness: 600 nm) formed by performing a first sputtering process (substrate temperature: 50° C., film thickness: 300 nm) and a second sputtering process (substrate temperature: 150° C., film thickness: 300 nm) (sample E), a semiconductor light-emitting device having an insulating film (film thickness: 600 nm) formed by performing a first sputtering process (substrate temperature: 200° C., film thickness: 300 nm) and a second sputtering process (substrate temperature: 300° C., film thickness: 300 nm) (sample F), a semiconductor light-emitting device having an insulating film (film thickness: 600 nm) formed by performing a first sputtering process (substrate temperature: 50° C., film thickness: 300 nm) and a second sputtering process (substrate temperature: 200° C., film thickness: 300 nm) (sample G), and a semiconductor light-emitting device having an insulating film (film thickness: 600 nm) formed by performing a first sputtering process (substrate temperature: 50° C., film thickness: 300 nm) and a second sputtering process (substrate temperature: 300° C., film thickness: 300 nm) (sample H). In the case of the sample B, the wafer was removed out of the sputtering device after each of the sputtering processes (that is, the sample B was exposed to the atmosphere twice). The manufacturing conditions other than those described above are the same as those in the first embodiment of the invention described before.

TABLE 2
Results of evaluation of substrate temperature when
forming the insulating film versus electrostatic withstand
voltage

| | | | | | Difference | | | |
|---|---|---|---|---|---|---|---|---|
| | Substrate | | Substrate | | in | | | |
| | temperature | | temperature | | substrate | | | |
| | when | | when | | temperature | | | |
| | performing | | performing | | at the time | | Electrostatic | |
| Sample | first | | second | | of film | | withstand | |
| name | sputtering | | sputtering | | formation | | voltage | |
| A | 50° C. | | | | 0° | C. | 6.25 | V |
| B | 50° | C. | 50° | C. | 0° | C. | 12.5 | V |
| C | 300° | C. | 300° | C. | 0° | C. | 12.0 | V |
| D | 50° | C. | 100° | C. | 50° | C. | 50 | V |
| E | 50° | C. | 150° | C. | 100° | C. | 55 | V |
| F | 200° | C. | 300° | C. | 100° | C. | 75 | V |
| G | 50° | C. | 200° | C. | 150° | C. | 80 | V |
| H | 50° | C. | 300° | C. | 250° | C. | 100 | V |

FIG. 8A is a graph obtained by plotting the results of the samples A and C with the horizontal axis representing the substrate temperature (° C.) and the vertical axis representing the electrostatic withstand voltage (V). FIG. 8B is a graph obtained by plotting the results of the samples A and B with the horizontal axis representing the number of exposures of the sample to the atmosphere and the vertical axis representing the electrostatic withstand voltage (V). FIG. 8C is a graph obtained by plotting the results of the samples D, E, G, and H with the horizontal axis representing the difference in the substrate temperature (° C.) at the time of the film formation and the vertical axis representing the electrostatic withstand voltage (V). FIG. 8D is a graph obtained by plotting the results of the samples E and F with the horizontal axis representing the substrate temperature (° C.) when performing the first sputtering process and the vertical axis representing the electrostatic withstand voltage (V).

First, Table 2 shows that the electrostatic withstand voltage of a semiconductor light-emitting device significantly increases when the difference between the substrate temperature when performing the first sputtering process and the substrate temperature when performing the second sputtering process (that is, the difference in temperature when forming the insulating film) is 50° C. or greater. The reason for this is believed to be that the pinholes in the first insulating layer formed in the first sputtering process are discontinuous with the pinholes in the second insulating layer formed in the second sputtering process at the interface between the first and second insulating layers.

As shown in FIG. 8A, when the substrate temperature at the time of the film formation increases by 250° C., the resultant electrostatic withstand voltage is about twice the electrostatic withstand voltage obtained when the substrate temperature is low. That is, it is found that the electrostatic withstand voltage depends on the substrate temperature at the time of the film formation, and a higher substrate temperature at the time of the film formation can provide a higher electrostatic withstand voltage. The reason for this is believed to be that raising the substrate temperature at the time of the film formation lowers the density of the pinholes in the insulating film. The conditions for the sample C, in which the substrate temperature at the time of the film formation is increased, however, cannot provide the significantly high electrostatic withstand voltages of the samples D to H, which were processed with the difference in the temperature when forming the insulating film set to 50° C. or higher.

As shown in FIG. 8B, when the wafer was exposed to the atmosphere between the first and second sputtering processes and between the second and third sputtering processes, the resultant electrostatic withstand voltage was about twice the electrostatic withstand voltage obtained when the wafer was not exposed to the atmosphere. The reason for this is that exposing the wafer to the atmosphere reduces the probability of the pinholes in the first insulating layer formed in the first sputtering process affecting the pinholes in the second insulating layer formed in the second sputtering process, and increases the probability of the pinholes in the first insulating layer formed before the wafer is exposed to the atmosphere being discontinuous with the pinholes in the second insulating layer formed after the wafer is exposed to the atmosphere. The relationship between the pinholes in the second insulating layer formed in the second sputtering process and the pinholes in the third insulating layer formed in the third sputtering process is the same as the relationship between the pinholes in the first insulating layer and the pinholes in the second insulating layer.

FIG. 8C shows that the electrostatic withstand voltage of a semiconductor light-emitting device increases with the difference between the substrate temperature of the first sputtering process and the substrate temperature of the second sputtering process. The reason for this is believed to be that increasing the difference in the substrate temperature between the film formation processes increases the difference in the pinhole distribution in the first insulating layer formed in the first sputtering process and the pinhole distribution in the second insulating layer formed in the second sputtering process and hence reduces the probability of the pinholes in the first insulating layer from continuing to be formed in the second insulating layer.

As shown in FIG. 8D, even when the difference in the film formation temperature when forming the insulating film is fixed, increasing the substrate temperatures in the sputtering processes provides an electrostatic withstand voltage about 1.4 times the electrostatic withstand voltage obtained when the substrate temperatures in the sputtering processes are low. The reason for this is believed to be that increasing the substrate temperature at the time of the film formation reduces the density of the pinholes in the insulating film.

As described above, by carrying out the semiconductor light-emitting device manufacturing method according to the first embodiment of the invention, the insulating film 22 formed between the semiconductor growth film 20 and the support member 25 has a multilayer structure having the interface 60 that causes the pinholes 61 and 62 present in the first insulating layer 22a to be discontinuous with the pinholes 61 and 62 present in the second insulating layer 22b, which is adjacent to the first insulating layer 22a. Since the insulation property of the insulating film 22 is therefore improved, the insulating film can be thin with high heat conductivity provided. Further, the withstand voltage and the heat dissipation ability of the semiconductor light-emitting device 50 can be improved.

Moreover, in the semiconductor light-emitting device manufacturing method according to the first embodiment of the invention, since the insulating film 22 is made of the same material and formed by carrying out the same film formation process, the semiconductor light-emitting device 50 can be manufactured at a reduced cost and in a simplified film formation step.

### Second Embodiment

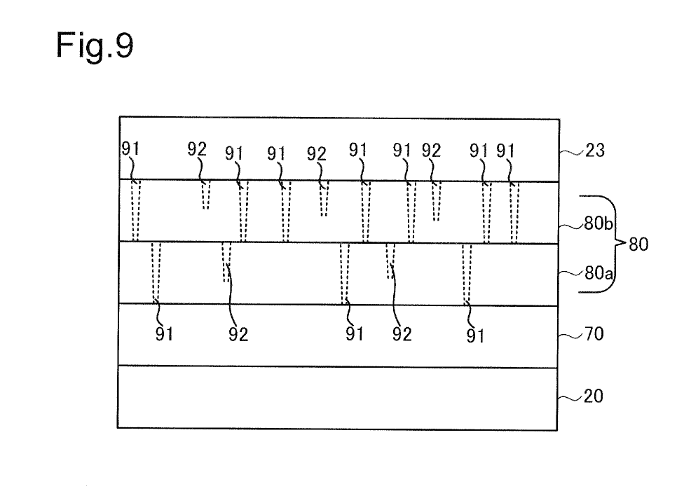

In the first embodiment of the invention, the substrate temperature when forming the first insulating layer 22a is set to be lower than the substrate temperature when forming the second insulating layer 22b. Alternatively, the first insulating layer may be formed at a high substrate temperature, and then the second insulating layer may be formed at a low substrate temperature. A semiconductor light-emitting device manufacturing method including the film formation steps described above and an insulating film formed by carrying out the manufacturing method will be described below with reference to FIG. 9. FIG. 9 is an enlarged, diagrammatic cross-sectional view for describing the internal structure of an insulating film that forms a semiconductor light-emitting element according to a second embodiment of the invention. The manufacturing steps of the first and second embodiments of the invention only differ from each other in terms of the p-side electrode formation step and the insulating film formation step, and therefore only these steps will be described below.

### [P-Side Electrode Formation Step]

A p-side electrode 70 is formed on the semiconductor growth film 20. More specifically, Pt (1 nm), an Ag alloy (150 nm), and Ti (100 nm) are sequentially stacked to cover the surface of the p-GaN layer 17 of the semiconductor growth film 20 in an electron beam evaporation process so as to form the p-side electrode 70 made of Pt/Ag alloy/Ti. The thickness of each of the metal layers described above is presented only by way of example and can be changed as appropriate. For example, the thickness of the Ti layer can be changed to a value in a range from 0.1 to 100 nm. Further, Pt in the p-side electrode 70 may be replaced with ITO. The p-side electrode 70 has the stacked metal structure described above which allows the p-side electrode 70 to be in intimate contact with the semiconductor growth film 20, providing an excellent ohmic connection therewith. Further, the p-side electrode 70 efficiently reflects light emitted from the active layer 15.

### [Insulating Film Formation Step]

An insulating film 80 having a two-layer structure is next formed on the p-side electrode 70. Specifically, a first insulating layer 80a made of SiO₂ is first formed to a thickness of about 150 nm by a sputtering process. The sputtering is performed under the following conditions: a substrate temperature of about 300° C. (i.e., temperature with performing heating), a high-frequency electric power (RF power) of 500 W, a total pressure ranging from 0.07 to 0.1 Pascal (Pa), and an atmosphere gas partial pressure ratio of Ar:O₂=95%:5%. A second insulating layer 80b made of SiO₂ is then formed to a thickness of about 150 nm in a sputtering process. The sputtering is performed under the following conditions: a substrate temperature of about 50° C. (i.e., temperature without performing heating), a high-frequency electric power (RF power) of 500 W, a total pressure ranging from 0.07 to 0.1 Pascal (Pa), and an atmosphere gas partial pressure ratio of Ar:O₂=95%:5%. That is, the step for forming the first insulating layer 80a differs from the step for forming the second insulating layer 80b only in terms of substrate temperature (that is, film formation temperature) and the other conditions are the same.

The thickness of each of the first insulating layer 80a and the second insulating layer 80b may range from 50 to 600 nm. Further, the substrate temperature when forming the first insulating layer 80a may range from 150 to 300° C. Moreover, the Ti that forms the p-side electrode 70 may be formed in a sputtering process before the first insulating layer 80a is formed.

The first insulating layer 80a and the second insulating layer 80b have a plurality of pinholes 91 that penetrate therethrough and a plurality of pinholes 92 that do not penetrate therethrough (that is, those that start in the insulating layers). Each of the pinholes 91 and 92 has a microscopic dimension. The number of pinholes 91 and 92 present in the second insulating layer 80b is greater than the number of pinholes 91 and 92 present in the first insulating layer 80a. That is, the density of the pinholes in the second insulating layer 80b is higher than that in the first insulating layer 80a. The reason why there is a difference in pinhole density is that the substrate temperature when forming the second insulating layer 80b being 50° C. and the substrate temperature when forming the first insulating layer 80a being 300° C. cause the residual stress in the second insulating layer 80b to be smaller than that in the first insulating layer 80a. When there is a difference in the residual stress between the insulating layers, the pinholes 91 and 92 are produced in the second insulating layer 80b without being affected by the pinholes 91 and 92 present in the first insulating layer 80a. As a result, the pinholes 91 present in the first insulating layer 80a are not continuous with the pinholes 91 present in the second insulating layer 80b at the interface 90 between the first insulating layer 80a and the second insulating layer 80b. That is, the interface 90 prevents the pinholes from penetrating through the insulating film 80.

When no pinhole penetrating through the insulating film 80 is present, metal atoms that form the p-side electrode 70 and the bonding portion 23, which sandwich the insulating film 80, can be prevented from migrating and no short path is produced in the insulating film 80, whereby the withstand voltage and reliability of the insulating film 80 can be improved.

Further, in the second embodiment of the invention, since the p-side electrode 70 contains an Ag alloy, whose characteristics will not greatly degrade even at high temperatures, the first insulating layer 80a can be formed at a high temperature (substrate temperature: 300° C.) In this way, an insulating layer having a low pinhole density can be formed on the p-side electrode 70 containing an Ag alloy, which tends to cause migration. Migration can be thus suppressed in a more satisfactory manner than in the first embodiment of the invention.

### Third Embodiment

In the first embodiment of the invention, each of the first insulating layer 22a and the second insulating layer 22b is formed by a sputtering process, and the first insulating layer 22a and the second insulating layer 22b are made of SiO₂ (that is, the layers are formed by carrying out the same film formation method and made of the same material). The first and second insulating layers are not necessarily formed this way. The insulating film 22 may alternatively be formed by carrying out different film formation methods and with different materials, as will be described below. The difference in manufacturing conditions between the following method and the method according to the first embodiment of the invention is only the insulating film formation step, and therefore only this step will be described below.

An insulating film 22 having a two-layer structure is formed on the semiconductor growth film 20. Specifically, a first insulating layer 22a made of SiO₂ is first formed to a thickness of about 150 nm by a sputtering process. The sputtering is performed under the following conditions: a substrate temperature of about 300° C., a high-frequency electric power (RF power) of 500 W, a total pressure ranging from 0.07 to 0.1 Pascal (Pa), and an atmosphere gas partial pressure ratio of Ar:O₂=95%:5%. A second insulating layer 22b made of SiN is then formed to a thickness of about 150 nm by a plasma CVD process. The plasma CVD is performed under the following conditions: a substrate temperature of about 300° C., a high-frequency electric power (RF power) of 200 W, a total pressure of about 67 Pa (500 milli-Torr (mTorr)), and an atmosphere gas partial pressure ratio of SiN₄:N₂=20%:80%. In other words, in the third embodiment of the invention, the step for forming the first insulating layer 22a differs from the step for forming the second insulating layer 22b not in terms of substrate temperature at the time of the film formation but in terms of film formation method and film formation material.

The thickness of each of the first insulating layer 22a and the second insulating layer 22b may range from 50 to 600 nm. Further, in the third embodiment of the invention described above, in which the insulating film 22 is formed by sputtering and plasma CVD processes, the insulating film 22 may alternatively be formed by, .e.g., a process combining thermal CVD with sputtering or by a process combining sputtering with electron beam evaporation. In particular, when the p-side electrode 21 contains ITO and Ag, the combination of thermal CVD with sputtering is effective. Further, in the third embodiment of the invention described above, in which the insulating film 22 is made of SiO₂ and SiN, the insulating film 22 may alternatively be made of any combination of SiO₂, SiN, Al₂O₃, and AlN as appropriate.

By carrying out the semiconductor light-emitting device manufacturing method according to the third embodiment of the invention, the insulating film 22 can be formed between the semiconductor growth film 20 and the support member 25 has a multilayer structure having an interface 60 that causes the pinholes 61 and 62 present in the first insulating layer 22a to be discontinuous with the pinholes 61 and 62 present in the second insulating layer 22b, which is adjacent to the first insulating layer 22a. Since the insulation property of the insulating film 22 is therefore also enhanced by carrying out the semiconductor light-emitting device manufacturing method according to the third embodiment of the invention, the insulating film can be thin with high heat conductivity provided. Further, the withstand voltage and the heat dissipation ability of the semiconductor light-emitting device 50 can be improved.

### Fourth Embodiment

In the first embodiment of the invention, each of the first insulating layer 22a and the second insulating layer 22b is formed by a sputtering process, and the first insulating layer 22a and the second insulating layer 22b are made of SiO₂ (that is, the layers are formed by carrying out the same film formation method and made of the same material). The first and second insulating layers are not necessarily formed this way. The insulating film 22 may alternatively be formed by carrying out different film formation methods and made of the same material, as will be described below. The difference in manufacturing conditions between the following method and the method according to the first embodiment of the invention is only the insulating film formation step, and therefore only this step will be described below.

An insulating film 22 having a two-layer structure is formed on the semiconductor growth film 20. Specifically, a first insulating layer 22a made of SiO₂ is first formed to a thickness of about 150 nm by a sputtering process. The sputtering is performed under the following conditions: a substrate temperature of about 300° C., a high-frequency electric power (RF power) of 500 W, a total pressure ranging from 0.07 to 0.1 Pascal (Pa), and an atmosphere gas partial pressure ratio of Ar:O₂=95%:5%. A second insulating layer 22b made of SiO₂ is then formed to a thickness of about 150 nm by a plasma CVD process. The plasma CVD is performed under the following conditions: a substrate temperature of about 300° C., a high-frequency electric power (RF power) of 200 W, a total pressure of about 20 Pa (150 mTorr), the flow rate of a mixture gas of SiN₄:N₂=20%:80% being 20 sccm, and the flow rate of N₂O gas being 30 sccm. In other words, in the fourth embodiment of the invention, the step for forming the first insulating layer 22a differs from the step for forming the second insulating layer 22b not in terms of substrate temperature at the time of film formation but in terms of film formation method.

The thickness of each of the first insulating layer 22a and the second insulating layer 22b may range from 50 to 600 nm. In the fourth embodiment of the invention described above, in which the insulating film 22 is formed by sputtering and plasma CVD processes, the insulating film 22 may alternatively be formed, for example, by a process combining thermal CVD with sputtering or by a process combining sputtering with electron beam evaporation. In particular, when the p-side electrode 21 contains ITO and Ag, the combination of thermal CVD with sputtering is effective. Further, in the fourth embodiment of the invention described above, in which the insulating film 22 is made of SiO₂, the insulating film 22 may alternatively be made of SiN, Al₂O₃, or AlN.

By carrying out the semiconductor light-emitting device manufacturing method according to the fourth embodiment of the invention, the insulating film 22 can be formed between the semiconductor growth film 20 and the support member 25 also has a multilayer structure having an interface 60 that causes the pinholes 61 and 62 present in the first insulating layer 22a to be discontinuous with the pinholes 61 and 62 present in the second insulating layer 22b, which is adjacent to the first insulating layer 22a. Since the insulation property of the insulating film 22 is therefore also enhanced by carrying out the semiconductor light-emitting device manufacturing method according to the fourth embodiment of the invention, the insulating film can be thin with high heat conductivity provided. Further, the withstand voltage and the heat dissipation ability of the semiconductor light-emitting device 50 can be improved.

### Fifth Embodiment

In the first embodiment of the invention, each of the first insulating layer 22a and the second insulating layer 22b is formed by a sputtering process, and the first insulating layer 22a and the second insulating layer 22b are made of SiO₂ (that is, the layers are formed by carrying out the same film formation method and made of the same material). The first and second insulating layers are not necessarily formed this way. The insulating film 22 may alternatively be formed by carrying out the same film formation method and made of different materials, as will be described below. The difference in manufacturing conditions between the following method and the method according to the first embodiment of the invention is only the insulating film formation step, and therefore only this step will be described below.

An insulating film 22 having a two-layer structure is formed on the semiconductor growth film 20. Specifically, a first insulating layer 22a made of SiO₂ is first formed to a thickness of about 150 nm by a plasma CVD process. The plasma CVD is performed under the following conditions: a substrate temperature of about 300° C., a high-frequency electric power (RF power) of 200 W, a total pressure of about 20 Pa (150 mTorr), the flow rate of a mixture gas of SiN₄:N₂=20%:80% being 20 sccm, and the flow rate of N₂O gas being 30 sccm. A second insulating layer 22b made of SiN is then formed to a thickness of about 150 nm in a plasma CVD process. The plasma CVD is performed under the following conditions: a substrate temperature of about 300° C., a high-frequency electric power (RF power) of 200 W, a total pressure of about 67 Pa (500 mTorr), and an atmosphere gas partial pressure ratio of SiN₄:N₂=20%:80%. In other words, in the fifth embodiment of the invention, the step for forming the first insulating layer 22a differs from the step for forming the second insulating layer 22b not in terms of substrate temperature at the time of film formation but in terms of film formation material.

The thickness of each of the first insulating layer 22a and the second insulating layer 22b may range from 50 to 600 nm. In the fifth embodiment of the invention described above, in which the insulating film 22 is formed by a plasma CVD process, the insulating film 22 may alternatively be formed by a sputtering process. Further, in the fifth embodiment of the invention described above, in which the insulating film 22 is made of SiO₂ and SiN, the insulating film 22 may alternatively be made of any combination of SiO₂, SiN, Al₂O₃, and AlN as appropriate.

By carrying out the semiconductor light-emitting device manufacturing method according to the fifth embodiment of the invention, the insulating film 22 can be formed between the semiconductor growth film 20 and the support member 25 also has a multilayer structure having an interface 60 that causes the pinholes 61 and 62 present in the first insulating layer 22a to be discontinuous with the pinholes 61 and 62 present in the second insulating layer 22b, which is adjacent to the first insulating layer 22a. Since the insulation property of the insulating film 22 is therefore also enhanced by carrying out the semiconductor light-emitting device manufacturing method according to the fifth embodiment of the invention, the insulating film can be thin while providing high heat conductivity. Further, the withstand voltage and the heat dissipation ability of the semiconductor light-emitting device 50 can be improved.

The invention has been described with reference to the preferred embodiments thereof. It should be understood by those skilled in the art that a variety of alterations and modifications may be made from the embodiments described above. It is therefore contemplated that the appended claims encompass all such alterations and modifications.

This application is based on Japanese Patent Application No. 2010-204353 which is hereby incorporated by reference.

What is claimed is:

1. A semiconductor light-emitting device manufacturing method comprising the steps of:
forming a semiconductor growth film on a growth substrate;
forming a metal film on said semiconductor growth film;
forming a multilayer insulating film on said metal film, said multilayer insulating film having at least a first insulating layer and a second insulating layer adjacent to each other; and
forming a support member on said multilayer insulating film,
wherein pinholes present in said first insulating layer are discontinuous with pinholes present in said second insulating layer at an interface between said first insulating layer and said second insulating layer.

2. The manufacturing method according to claim 1, wherein
in the step of forming said multilayer insulating film, a pinhole density in said first insulating layer is set to be lower than a pinhole density in said second insulating layer.

3. The manufacturing method according to claim 2, wherein
in the step for forming said multilayer insulating film, a substrate temperature when forming said first insulating layer differs from a substrate temperature when forming said second insulating layer by at least 50° C., and said first insulating layer and said second insulating layer are formed by stacking the same insulating material by carrying out the same film formation method.

4. The manufacturing method according to claim 1, wherein
in the step of forming said multilayer insulating film, said first insulating layer and said second insulating layer are formed by stacking insulating materials different from each other by carrying out film formation methods different from each other.

5. The manufacturing method according to claim 1, wherein
in the step of forming said multilayer insulating film, said first insulating layer and said second insulating layer are formed by stacking the same insulating material by carrying out film formation methods different from each other.

6. The manufacturing method according to claim 1, wherein
in the step of forming said multilayer insulating film, said first insulating layer and said second insulating layer are formed by stacking insulating materials different from each other by carrying out the same film formation method.

7. A semiconductor light-emitting device manufacturing method comprising the steps of:
forming a semiconductor growth film on a growth substrate;
forming a metal film on said semiconductor growth film;
forming a multilayer insulating film formed of a first insulating layer and a second insulating layer by stacking the same insulating material on said metal film by a sputtering process; and
forming a support member on said multilayer insulating film,
wherein in the step of forming said multilayer insulating film, a substrate temperature when forming said first insulating layer differs from a substrate temperature when forming said second insulating layer by at least 50° C.

8. The manufacturing method according to claim 7, wherein
in the step of forming said multilayer insulating film, the substrate temperature when forming said first insulating layer is higher than the substrate temperature when forming said second insulating layer.

9. A semiconductor light-emitting device comprising:
a multilayer insulating film formed on a support member and having at least a first insulating layer and a second insulating layer adjacent to each other;
a metal film formed on said multilayer insulating film; and
a semiconductor growth film formed on said metal film,
wherein pinholes present in said first insulating layer are discontinuous with pinholes present in said second insulating layer at an interface between said first insulating layer and said second insulating layer.

10. The semiconductor light-emitting device according to claim 9, wherein
a pinhole density in said first insulating layer is lower than a pinhole density in said second insulating layer.
